(19) United States
(12) Patent Application Publication
(10) Pub. No.: US 2026/0149451 A1
(43) Pub. Date: May 28, 2026

(54) IMPEDANCE CALIBRATION CIRCUIT AND IMPEDANCE CALIBRATION METHOD

(71) Applicant: CXMT Corporation, Hefei City (CN)

(72) Inventors: Jie ZENG, Hefei City (CN); Xiaochen ZHANG, Hefei City (CN)

(73) Assignee: CXMT Corporation, Hefei City (CN)

(21) Appl. No.: 19/437,111

(22) Filed: Dec. 30, 2025

Related U.S. Application Data
(63) Continuation of application No. PCT/CN2025/080725, filed on Mar. 5, 2025.

(30) Foreign Application Priority Data
Nov. 26, 2024 (CN) 202411709317.2

(51) Int. Cl. H03K 19/00; G11C 7/10

(52) U.S. Cl. CPC H03K 19/0005; G11C 7/1048; G11C 2207/2254

(57) ABSTRACT

Disclosed is an impedance calibration control circuit, including: a calibration control circuit, configured to output a first calibration code; logic conversion circuits, configured to receive the first calibration code and a second calibration code, perform calculation on the first calibration code and the second calibration code, and then output a third calibration code; and multiple calibrated units, configured to receive the third calibration code and adjust impedance based on the third calibration code.

### CROSS-REFERENCE TO RELATED APPLICATIONS

This application is a continuation of International Patent Application No. PCT/CN2025/080725, filed on Mar. 5, 2025, which claims priority to Chinese Patent Application No. 202411709317.2, filed on Nov. 26, 2024. The disclosures of the above-referenced applications are hereby incorporated by reference in their entirety.

### TECHNICAL FIELD

Embodiments of the present disclosure relate to the field of semiconductor technologies, and in particular, to an impedance calibration circuit and an impedance calibration method.

### BACKGROUND

With the rapid development of semiconductor technology, a rise time of signals is becoming shorter and shorter, which leads to the increasingly prominent signal integrity problem. To better improve signal integrity on a data line during propagation of high-speed signals, in designs of a DDR3 and a DDR4, an on-die termination (On Die Termination, ODT) resistor and an output driver resistor are separately added, that is, the ODT resistor and the output driver resistor are configured to match impedance of a transmission line. This reduces an energy loss and reflection of signals during transmission, thereby ensuring correctness and integrity of signals received by a receiving end. Accuracy of the ODT resistor and the output driver resistor is an important parameter to improve correctness and integrity of signals. Due to the influence of chip production, testing, and packaging technologies, there are often specific errors in actual resistance values of the ODT resistor and the output driver resistor. Moreover, due to the errors, adjustment accuracy, and the like, adjustment linearities of the ODT resistor and the output driver resistor in related technologies are poor, a required standard design resistance value cannot be obtained accurately, and a matching degree with resistance of the transmission line is also poor. Therefore, a memory needs to calibrate resistance values of a related ODT resistor and output driver resistor, that is, perform ZQ calibration.

In a design of an integrated circuit, different ODT resistors and output driver resistors usually share the same ZQ calibration result, to simplify the design and ensure signal integrity. However, due to the process, even after calibration, the ODT resistor and the output driver resistor corresponding to part of DQ may be adjusted to desired resistance values, an ODT resistance value and output driver resistance corresponding to other DQ may exceed a desired range. Consequently, for different DQ in the same memory, there is a great difference between ODT resistance values and there is a great difference between output driver resistances. The inconsistency between the ODT resistance values and the inconsistency between the output driver resistances have a negative impact on signal integrity in testing of high-speed data transmission. This may lead to signal reflection, crosstalk, and other problems, thereby affecting accuracy and system performance of data transmission. Therefore, how to reduce errors of ZQ calibration is an urgent technical problem that a person skilled in the art needs to solve.

### SUMMARY

According to some embodiments of the present disclosure, an aspect of embodiments of the present disclosure provides an impedance calibration control circuit, including:
a calibration control circuit, configured to output a first calibration code;
logic conversion circuits, configured to receive the first calibration code and a second calibration code, perform calculation on the first calibration code and the second calibration code, and then output a third calibration code; and multiple calibrated units, configured to receive the third calibration code and adjust impedance based on the third calibration code.

According to some embodiments of the present disclosure, another aspect of embodiments of the present disclosure further provides an impedance calibration method, including the steps as follows.

An initial reference voltage of an impedance calibration circuit is determined, and the initial reference voltage is latched.

Multiple calibrated units of the impedance calibration circuit are traversed under the initial reference voltage until a calibrated resistance value of each of the calibrated units is adjusted to a target resistance value.

The technical solutions provided in the embodiments of the present disclosure have at least the following advantages.

On the one hand, logic conversion circuits are arranged between a calibration control circuit and calibrated units. The logic conversion circuits are configured to receive a first calibration code and a second calibration code, perform calculation on the first calibration code and the second calibration code, and then output a third calibration code. Multiple calibrated units are configured to receive the third calibration code, adjust interface impedance of a memory, and finely adjust an adjusted resistance value of each of the calibrated units, so that a calibrated resistance value of each of the calibrated units can reach a target resistance value.

On the other hand, after an initial reference voltage of an impedance calibration control circuit is determined and the initial reference voltage is latched, under the initial reference voltage, multiple calibrated units of the impedance calibration control circuit are traversed until a calibrated resistance value of each of the calibrated units is a target resistance value, thereby adjusting the calibrated resistance value of each of the calibrated units, improving consistency of different impedance adjustments, and further ensuring signal integrity during data transmission.

### BRIEF DESCRIPTION OF DRAWINGS

One or more embodiments are exemplified with the figures in the accompanying drawings corresponding to the one or more embodiments. These example descriptions are not intended to limit the embodiments, and unless specifically stated, no scale limitations are constituted by the figures in the accompanying drawings. To describe the technical solutions in the embodiments of the present disclosure or the conventional technologies more clearly, the accompanying drawings required by the embodiments are briefly described below. Clearly, the accompanying drawings in the following description show merely some embodiments of the present disclosure, and other drawings may be obtained by a person of ordinary skill in the art from these accompanying drawings without creative efforts.

FIG. 1 is a functional block diagram of an impedance calibration circuit according to an embodiment of the present disclosure;

FIG. 2 is a schematic diagram of a circuit structure of a calibrated unit according to an embodiment of the present disclosure;

FIG. 3 is a flowchart of a calibration method according to an embodiment of the present disclosure;

FIG. 4 is a functional block diagram of a memory according to an embodiment of the present disclosure; and

FIG. 5 is a functional block diagram of a storage system according to an embodiment of the present disclosure.

### DESCRIPTION OF EMBODIMENTS

In a design of an integrated circuit, to meet the challenge of signal integrity in high-speed data transmission, on-die termination (ODT, on-die termination) and output driver resistor technologies are widely used. ODT implements impedance matching by integrating termination resistors in a memory, thereby effectively reducing signal reflection and improving signal quality. In high-speed signal transmission, an output driver resistor matches load resistance and characteristic impedance of a transmission line, which can reduce the signal reflection and signal integrity problems. However, due to technical limitations in the process of chip production, testing, and packaging, actual resistance values of an ODT resistor and the output driver resistor may deviate from design values. This deviation affects correctness and integrity of signals, and especially in a scenario of high-speed data transmission, a small difference in resistance value may also lead to signal reflection and crosstalk, thereby affecting accuracy of data transmission and overall performance of a system.

To overcome this problem, a ZQ calibration mechanism is introduced into the memory design. ZQ calibration is a calibration process to adjust resistance values of the ODT resistor and the output driver resistor to make the resistance values match a design standard. Through the ZQ calibration, the ODT resistor and the output driver resistor can be adjusted to make the resistance values thereof closer to ideal impedance of the transmission line, thereby improving signal integrity. In design, ODT resistors and output driver resistors on different DQ lines usually share the same ZQ calibration result, to simplify the design and ensure consistency of signal integrity. However, due to a difference in process, even after ZQ calibration, resistance values of the ODT resistors and resistance values of the output driver resistors on different DQ lines may still be different. This difference may lead to signal crosstalk. Especially in testing of high-speed data transmission, this difference has a negative impact on signal integrity, and then affects accuracy of data transmission and system performance.

To solve the above-mentioned technical problems, embodiments of the present disclosure provide an impedance calibration control circuit and an impedance calibration method. Embodiments of the present disclosure are described in detail below with reference to the accompanying drawings. However, it may be understood by a person of ordinary skill in the art that in the embodiments of the present disclosure, many technical details are provided to enable readers to better understand the present disclosure. However, the technical solutions claimed in the present disclosure may be implemented even without these technical details and various changes and modifications made based on the following embodiments.

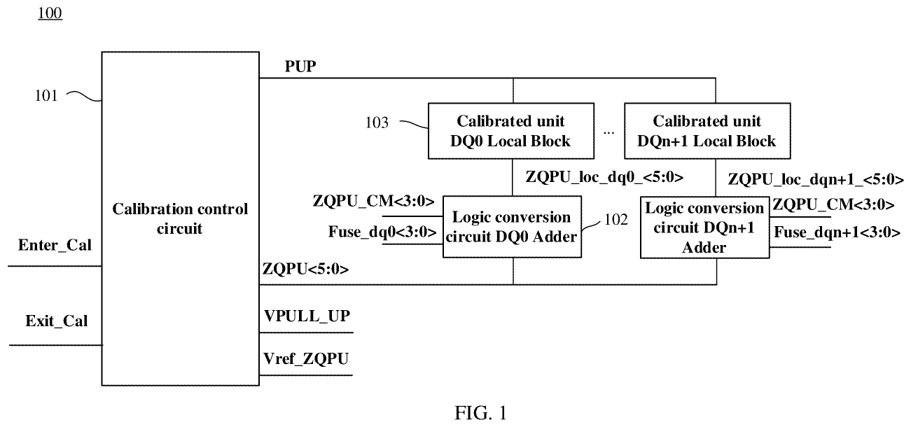

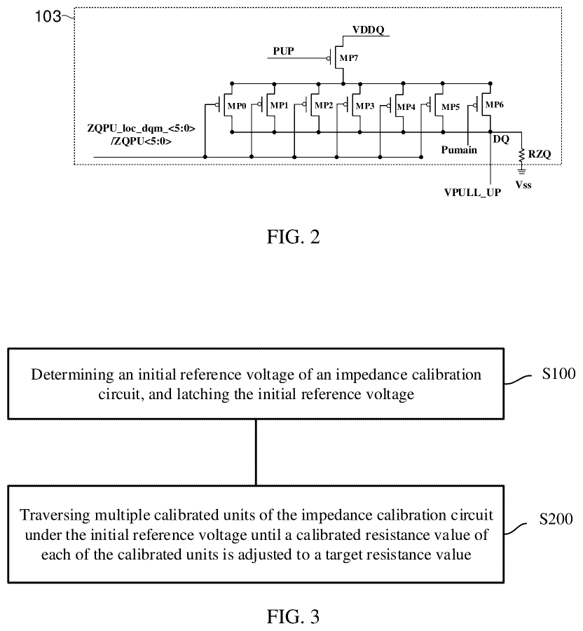

An impedance calibration control circuit according to an embodiment of the present disclosure is described below with reference to the accompanying drawings. FIG. 1 is a functional block diagram of an impedance calibration circuit according to an embodiment of the present disclosure. FIG. 2 is a schematic diagram of a circuit structure of a calibrated unit according to an embodiment of the present disclosure.

Referring to FIG. 1, an impedance calibration circuit 100 according to an embodiment of the present disclosure includes: a calibration control circuit 101, configured to output a first calibration code ZQPU<5:0>; logic conversion circuits 102, configured to receive the first calibration code ZQPU<5:0> and a second calibration code ZQPU_CM<3:0>, perform calculation on the first calibration code ZQPU<5:0> and the second calibration code ZQPU_CM<3:0>, and then output a third calibration code ZQPU_loc_dqm_<5:0>; and multiple calibrated units 103, configured to receive the third calibration code ZQPU_loc_dqm_<5:0> and adjust impedance based on the third calibration code ZQPU_loc_dqm_<5:0>.

In some embodiments, the calibration control circuit 101 is further configured to receive a data calibration command Enter_Cal and an exit calibration command Exit_Cal. For example, the calibration control circuit 101 starts to calibrate the calibrated units 103 after receiving the data calibration command Enter_Cal, and stops calibrating the calibrated units 103 after receiving the exit calibration command Exit_Cal. Specifically, when the calibration control circuit 101 starts to calibrate the calibrated units 103 after receiving the data calibration command Enter_Cal, a power control signal PUP is driven to a low level by the calibration control circuit 101. In this case, a PMOS transistor MP7 connected to a VDDQ is turned on to provide a source voltage in the process of calibrating the calibrated units 103.

In some embodiments, the logic conversion circuits 102 are configured to receive the first calibration code ZQPU<5:0> and the second calibration code ZQPU_CM<3:0>, perform calculation on the first calibration code ZQPU<5:0> and the second calibration code ZQPU_CM<3:0>, and then output the third calibration code ZQPU_loc_dqm_<5:0>. The first calibration code ZQPU<5:0> denotes a set of calibration codes corresponding to ZQPU<0> to ZQPU<5>. The second calibration code ZQPU_CM<3:0> denotes a set of calibration codes corresponding to ZQPU_CM<0> to ZQPU_CM<3>. The third calibration code ZQPU_loc_dqm_<5:0> denotes a set of calibration codes corresponding to ZQPU_loc_dqm<0> to ZQPU_loc_dqm_<5>. The third calibration code ZQPU_loc_dqm_<5:0> may be any one of ZQPU_loc_dq0_<5:0> to ZQPU_loc_dqn+1_<5:0>. Specifically, in the process of calibrating the calibrated units 103, the first calibration code ZQPU<5:0> may be a fixed value. Each of the logic conversion circuits 102 may include a full adder. Calculation is performed on the first calibration code ZQPU<5:0> and the second calibration code ZQPU_CM<3:0> by the full adder to obtain the third calibration code ZQPU_loc_dqm_<5:0>. As shown in Table 1, for example, when the first calibration code ZQPU<5:0> is “000000” and the second calibration code ZQPU_CM<3:0> is “0000”, the third calibration code ZQPU_loc_dqm_<5:0>calculated by the full adder is “000000”. It may be understood that the calibrated units 103 may adjust calibrated resistance values of the calibrated units 103 to a target resistance value after receiving the third calibration code ZQPU_loc_dqm_<5:0>.

TABLE 1
Logic conversion table

| ZQPU<5:0> | ZQPU_CM<3:0> | ZQPU_loc_dqm_<5:0> |
|---|---|---|
| 000000 | 0000 | 000000 |
| 000000 | 0001 | 000001 |
| 000000 | 0010 | 000010 |
| 000000 | 0011 | 000011 |
| 000000 | 0101 | 000101 |
| 000000 | 0110 | 000110 |

In some embodiments, multiple logic conversion circuits 102 are correspondingly connected to the calibrated units 103. It may be understood that one logic conversion circuit 102 is correspondingly connected to one calibrated unit 103, so that the calibrated resistance value of each of the calibrated units 103 can be finely adjusted, and therefore the calibrated resistance value of each of the calibrated units 103 can reach the target resistance value. The target resistance value is a resistance value required for the calibrated units to calibrate interface impedance of the memory. That is, the target resistance value is set according to impedance calibration requirements of a data input/output signal DQ of the memory. For example, the target resistance value may be a calibrated resistance value specified in a design specification (SPEC: Standard Performance Evaluation Corporation). For example, referring to FIG. 1, multiple logic conversion circuits 102 (DQ₀ Adder, . . . , and DQn+1 Adder) respectively correspond to multiple calibrated units 103 (DQ₀ Local Block, . . . , and DQn+1 Local Block), where n may be an integer greater than or equal to 1. For example, n may be 14, multiple logic conversion circuits 102 may be DQ₀ Adder, . . . , and DQ15 Adder, and multiple calibrated units 103 may be DQ₀ Local Block, . . . , and DQis Local Block. Alternatively, n may be 6, multiple logic conversion circuits 102 may be DQ₀ Adder, . . . , and DQ7 Adder, and multiple calibrated units 103 may be DQ₀ Local Block, . . . , and DQ₇ Local Block. This is not limited herein.

In some embodiments, when the calibrated resistance values of the calibrated units 103 are adjusted to the target resistance value, the logic conversion circuits 102 are further configured to perform bias latching on the second calibration code ZQPU_CM<3:0>corresponding to the third calibration code ZQPU_loc_dqm_<5:0>. Specifically, the second calibration code ZQPU_CM<3:0>corresponding to the third calibration code ZQPU_loc_dqm_<5:0> may be burned through a redundant circuit corresponding to the logic conversion circuits 102, thereby implementing a fixed bias of the third calibration code ZQPU_loc_dqm_<5:0>. The third calibration code ZQPU_loc_dqm<5:0> may be any one of ZQPU_loc_dq0_<5:0> to ZQPU_loc_dqn+1_<5:0>. For example, referring to Table 1 and Table 2, in an example in which multiple logic conversion circuits 102 are DQ₀ Adder, . . . , and DQ₇ Adder and multiple calibrated units 103 are DQ₀ Local Block, . . . , and DQ₇ Local Block, when the target resistance value of the calibrated units 103 is 40Ω, after the calibrated unit 103 (DQ₀ Local Block) traverses ZQPU_CM<3:0>, it is confirmed that a level of a corresponding logic conversion circuit 102 is “1”. In this case, the logic conversion circuit 102 burns a bias level corresponding to ZQPU_CM<3:0> into a redundant circuit corresponding to the logic conversion circuit 102 (DQ₀ Adder), and then the first calibration code ZQPU<5:0> “000000” is fixedly subjected to a logical operation, in the logic conversion circuit 102, with a fixed calibration code Fuse_dq0<3:0> of the redundant circuit to obtain a third calibration code ZQPU_loc_dq0_<5:0>, namely, a third calibration code ZQPU_loc_dq0_<5:0> “000001” obtained after the logical operation of the second calibration code ZQPU_CM<3:0> “0001” corresponding to the level “1”. When the calibrated unit 103 (DQ1 Local Block) reaches the target resistance value, and the level of the corresponding logic conversion circuit 102 is “2”, the logic conversion circuit 102 burns a bias level corresponding to the second calibration code ZQPU_CM<3:0> “0010” corresponding to the level “2” into a redundant circuit corresponding to the logic conversion circuit 102 (DQ1 Adder), and then the first calibration code ZQPU<5:0> “000000” is fixedly subjected to a logical operation, in the logic conversion circuit 102, with a fixed calibration code Fuse_dq1<3:0> of the redundant circuit to obtain a third calibration code ZQPU_loc_dq1_<5:0> “000010”, namely, a third calibration code ZQPU_loc_dq1_<5:0>obtained after the logical operation of the second calibration code ZQPU_CM<3:0>corresponding to the level “2”, and so on, until resistance value adjustment of all the calibrated units 103 is completed. That is, the adjustment of all the calibrated units 103 is ended when the calibrated resistance values of all the calibrated units 103 reach the target resistance value. When the calibrated units 103 reach the target resistance value, the second calibration code ZQPU_CM<3:0>has the same value as the fixed calibration code Fuse_dq1<3:0>.

TABLE 2
Corresponding table of levels of calibrated units

| | | | DQ0 | DQ1 | DQ2 | DQ3 | DQ4 | DQ5 | DQ6 | DQ7 |
|---|---|---|---|---|---|---|---|---|---|---|
| | | | Local | Local | Local | Local | Local | Local | Local | Local |
| | ZQPU_CM | | Block/ | Block/ | Block/ | Block/ | Block/ | Block/ | Block/ | Block/ |
| ZQPU<5:0> | <3:0> | Level | Ω | Ω | Ω | Ω | Ω | Ω | Ω | Ω |
| 000000 | 0001 | 1 | 40 | 37 | 35 | 34 | 36 | 38 | 39 | 33 |
| 000000 | 0010 | 2 | 37 | 40 | 36 | 39 | 40 | 34 | 33 | 32 |
| 000000 | 0011 | 3 | 35 | 37 | 40 | 33 | 34 | 36 | 37 | 38 |
| 000000 | 0101 | 4 | 34 | 42 | 38 | 40 | 35 | 42 | 40 | 41 |
| 000000 | 0110 | 5 | 33 | 35 | 41 | 39 | 38 | 43 | 39 | 40 |
| 000000 | 0111 | 6 | 41 | 34 | 39 | 35 | 41 | 40 | 41 | 39 |

In some embodiments, referring to FIG. 1 and FIG. 2, the calibration control circuit 101 further includes a comparator. When calibrated resistance values of the calibrated units 103 are adjusted to the target resistance value, an adjusted first calibration code ZQPU<5:0> is finally outputted by comparing pull-up voltages VPULL_UP on both sides of a DQ pin with a target reference voltage Vref_ZQPU.

In some embodiments, before the logic conversion circuits 102 perform calculation on the first calibration code ZQPU<5:0> and the second calibration code ZQPU_CM<3:0>, the calibration control circuit 101 may first initially adjust the calibrated units 103 to determine an initial reference voltage Vref_ZQPU. Specifically, one of multiple calibrated units 103 may be selected as the initial calibrated unit. Under different reference voltages, an adjusted resistance value of the initial calibrated unit is adjusted until the calibrated resistance value of the initial calibrated unit is the target resistance value, and the initial reference voltage Vref_ZQPU corresponding to the target resistance value is determined and latched. It should be noted that when the calibration control circuit 101 initially calibrates the calibrated unit 103, the logic conversion circuits 102 may be in a non-operating state. That is, it may be understood that the calibration control circuit 101 is directly electrically connected to the calibrated unit 103, and the latched initial reference voltage Vref_ZQPU may be set as a reference voltage when the logic conversion circuits 102 perform a traversal logic operation on the first calibration code ZQPU<5:0> and the second calibration code ZQPU_CM<3:0>.

In some embodiments, referring to FIG. 2, a calibrated unit 103 is connected between a source voltage VDDQ and a DQ pin, and includes multiple metal oxide semiconductor (MOS) transistors connected in parallel, and the MOS transistors may be P-channel metal oxide semiconductor (PMOS) transistors. For example, the number of PMOS transistors may be set to 6 to 10 based on a calibrated resistance value specified according to SPEC, which is not limited herein. The calibration control circuit 103 may control turn-on of a different number of PMOS transistors by adjusting the first calibration code ZQPU<5:0>.

In some embodiments, each calibrated unit 103 is a pull-up calibrated unit, and multiple pull-up calibrated units are connected in parallel. In another embodiment, each calibrated unit 103 may alternatively be a pull-down conditioned circuit or a combination of a pull-up calibrated unit and a pull-down conditioned circuit, which is not limited herein. Referring to FIG. 2, in an example in which the calibrated unit 103 is a pull-up calibrated unit, the pull-up calibrated unit may include six pull-up transistors MP0 to MP5 connected in parallel. Before a logic conversion circuit 102 performs calculation on the first calibration code ZQPU<5:0> and the second calibration code ZQPU_CM<3:0>, each calibration code (one of first calibration codes ZQPU<0> to ZQPU <5>) of the first calibration code ZQPU<5:0>correspondingly turns on/off one pull-up transistor (one of the pull-up transistors MP0 to MP5). The pull-up transistors MP0 to MP5 may be PMOS transistors. For example, when the first calibration code ZQPU<5:0> is “000000”, the pull-up transistors MP0 to MP5 are all turned on. During calculation of the first calibration code ZQPU<5:0> and the second calibration code ZQPU_CM<3:0> by the logic conversion circuit 102, that is, when the calibrated unit 103 (DQ₀ Local Block) is calibrated, each calibration code (one of first calibration codes ZQPU <0> to ZQPU <5>) of the third calibration code ZQPU_loc_dq0_<5:0>correspondingly turns on/off one pull-up transistor (one of the pull-up transistors MP0 to MP5). For example, when the third calibration code ZQPU_loc_dq0_<5:0> is “000110”, the pull-up transistors MP0, MP3, MP4, and MP5 are turned on while MP1 and MP2 are turned off.

In addition, the pull-up calibrated unit further includes a comparison transistor MP6 connected in parallel to the pull-up transistors MP0 to MP5, and the source or the drain at one end of the comparison transistor MP6 is connected to the DQ pin. Referring to FIG. 2, the transistor MP6 can be controlled to remain in a normally open state through a normally open signal Pumain in the memory, to compare resistances at both sides of the DQ pin, so as to adjust impedance of the calibrated unit 103 according to a comparison result.

The DQ pin is a main channel for data exchange between the memory and an external system (such as a CPU or an internal memory controller). In a read operation, the DQ pin is configured to output data stored in the memory to the external system. In a write operation, the DQ pin is configured to receive data transmitted by the external system and store the data in the memory. For example, when DQ is employed as an output, the pull-up calibrated unit or a pull-down calibrated unit is connected to the DQ, and a calibrated resistance value outputted by the corresponding pull-up calibrated unit or the corresponding pull-down calibrated unit is adjusted by controlling the number of transistors turned on in the pull-up calibrated unit or the pull-down calibrated unit, so as to finally calibrate impedance of the DQ pin.

During the impedance calibration operation, the impedance calibration circuit 100 may adjust output impedance by comparing output impedance of the calibrated unit 103 with external standard resistance to meet the calibrated resistance value specified by the design specification (SPEC: Standard Performance Evaluation Corporation). In some embodiments, the calibrated unit 103 further includes a reference resistor RZQ, and the reference resistor RZQ has a resistance value of 40Ω to 240Ω. The reference resistor RZQ, as an external standard resistor, has a resistance value that does not change with environmental factors. When the calibrated resistance value of the calibrated unit 103 needs to be adjusted, the resistance value of the reference resistor RZQ may be employed as reference resistance to achieve accurate adjustment of the impedance of the calibrated unit 103. For example, when the calibrated unit 103 includes both a pull-up calibrated unit and a pull-down calibrated unit, the pull-down calibrated unit of the calibrated unit 103 may be first calibrated by externally connecting a standard resistor of 240 ohms, and then the pull-up calibrated unit of the calibrated unit 103 may be calibrated through the calibrated pull-down calibrated unit, so that the pull-up calibrated unit can also meet preset impedance requirements. Since the pull-up calibrated unit or the pull-down calibrated unit of the calibrated unit 103 includes transistors, an equivalent resistance value thereof is greatly affected by process, voltage, and temperature (PVT). As a result, a final calibration result may be deviated. In this embodiment, multiple logic conversion circuits 102 are correspondingly connected to the calibrated units 103, so that the calibrated resistance value of each of the calibrated units 103 can be finely adjusted, and the calibrated resistance value of each of the calibrated units 103 can reach the target resistance value. This avoids the deviation of the calibration result caused by process conditions, improves accuracy of the calibration result, and then ensures signal integrity.

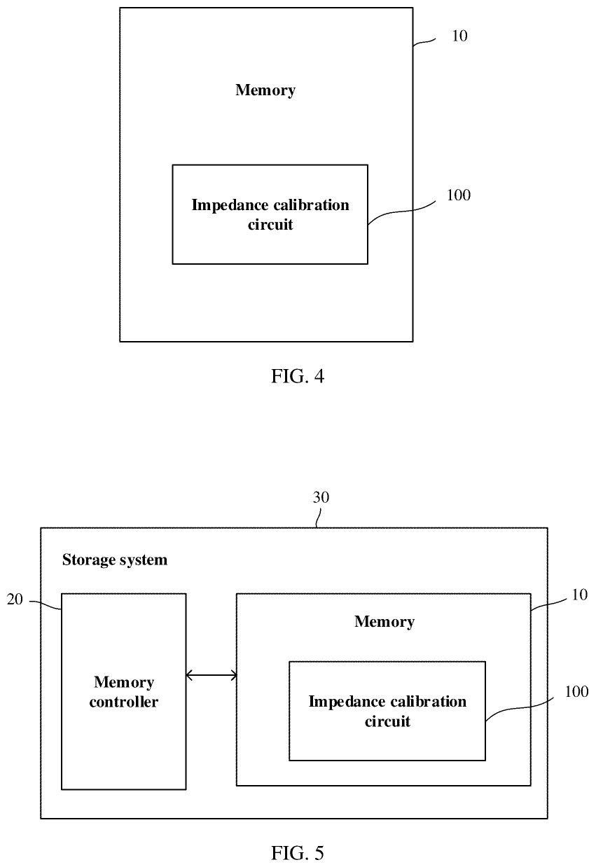

Correspondingly, another embodiment of the present disclosure provides an impedance calibration method. FIG. 3 is a flowchart of calibration according to an embodiment of the present disclosure. FIG. 4 is a functional block diagram of a memory according to an embodiment of the present disclosure. FIG. 5 is a functional block diagram of a storage system according to an embodiment of the present disclosure. The impedance calibration method according to this embodiment is described in detail below with reference to the accompanying drawings, and the parts same as or corresponding to those of the above-mentioned embodiments are not described in detail below.

In step S100, an initial reference voltage of an impedance calibration control circuit is determined, and the initial reference voltage is latched.

In some embodiments, referring to FIG. 1 to FIG. 3, that an initial reference voltage Vref_ZQPU of an impedance calibration control circuit 100 is determined, and the initial reference voltage Vref_ZQPU is latched includes the steps as follows. One of the calibrated units 103 is selected as an initial calibrated unit. A calibrated resistance value of the initial calibrated unit is adjusted under different reference voltages. When the calibrated resistance value of the initial calibrated unit is the target resistance value, the initial reference voltage Vref_ZQPU corresponding to the target resistance value is determined, and the initial reference voltage Vref_ZQPU is latched. Specifically, the number of calibrated units 103 may be 8, 16, or 32, which is not limited herein. One of the calibrated units 103 may be randomly selected as an initial calibrated unit or selected according to calibration requirements. It should be noted that when the calibration control circuit 101 initially calibrates the calibrated units 103, the logic conversion circuits 102 are in a non-operating state. That is, it may be understood that the calibration control circuit 101 is directly electrically connected to the calibrated units 103. A reference voltage is set by the calibration control circuit 101, and the value of the first calibration code ZQPU<5:0> is different under different reference voltages. For example, when the reference voltage is 260 mv, a corresponding first calibration code ZQPU<5:0> may be “000001”, or when the reference voltage is 240 mv, a corresponding reference voltage is “010010”. Referring to FIG. 2, the calibrated units 103 are configured to receive the first calibration code or the third calibration code, and in a stage in which the initial reference voltage of the impedance calibration control circuit 100 is determined, the calibrated units 103 are configured to receive the first calibration code, thereby turning on different numbers of PMOS transistors. In an example in which the calibrated unit 103 is a pull-up calibrated unit, the pull-up calibrated unit may include six pull-up transistors MP0 to MP5 connected in parallel. When the reference voltage is 260 mv, the first calibration code ZQPU<5:0> is “000001”, and the pull-up transistor MP0 is turned off, while MP1, MP2, MP3, MP4, and MP5 are turned on. If the initial calibrated unit reaches the target resistance value at this time, the reference voltage at this time is determined as the initial reference voltage Vref_ZQPU. For example, the initial reference voltage Vref_ZQPU at this time may be determined as 260 mv. After the initial reference voltage Vref_ZQPU is determined, a corresponding redundant circuit may alternatively be turned on by the calibration control circuit 101 to latch the initial reference voltage Vref_ZQPU at this time.

In some embodiments, when the initial calibrated unit is adjusted, reference voltages of the calibrated units 103 except the initial calibrated unit are the same as the reference voltage of the initial calibrated unit, that is, when the initial calibrated unit is adjusted, the remaining calibrated units are also adjusted synchronously. When the calibrated resistance value of the initial calibrated unit is adjusted to the target resistance value, it is determined that the reference voltage at this time is the initial reference voltage Vref_ZQPU. It should be noted that with the continuous reduction of the physical dimension of the memory, there are specific differences between transistors in different calibrated units 103 due to the impact of the process. When the initial calibrated unit reaches the target resistance value at the initial reference voltage, the remaining calibrated units 103 may exceed or fall below the target resistance value. This may affect signal integrity in the high-speed test. Therefore, the remaining calibrated units 103 need to be further calibrated, so that the remaining calibrated units can also reach the target resistance value.

In step S200, multiple calibrated units 103 are traversed under the initial reference voltage Vref_ZQPU until a calibrated resistance value of each of the calibrated units 103 is adjusted to a target resistance value. Specifically, referring to FIG. 1 to FIG. 3, when reaching the target resistance value under the initial reference voltage Vref_ZQPU, the initial calibrated unit may transmit a test command to a memory through a test bench to control the impedance calibration control circuit 100 to enter a test mode. The impedance calibration circuit 100 may include a calibration control circuit 101, logic conversion circuits 102, and multiple calibrated units 103. The calibration control circuit 101 is configured to generate a first calibration code ZQPU<5:0> for determining target resistance. The logic conversion circuits 102 are configured to receive the first calibration code ZQPU<5:0> and a second calibration code ZQPU_CM<3:0>. The second calibration code ZQPU_CM<3:0> may be a calibration code generated after the memory receives the test command transmitted by the test bench. It should be noted that after the test mode is entered, the first calibration code ZQPU<5:0> may remain unchanged during the calibration of the calibrated unit 103 when the initial reference voltage Vref_ZQPU is determined.

In some embodiments, the step that multiple calibrated units 103 of the impedance calibration circuit 100 are traversed under the initial reference voltage Vref_ZQPU until a calibrated resistance value of each of the calibrated units 103 is adjusted to a target resistance value further includes the step as follows. A bias level corresponding to the target resistance value of each of the calibrated units 103 is latched. For example, multiple logic conversion circuits 102 are correspondingly connected to the calibrated units 103. It may be understood that each of the logic conversion circuits 102 is correspondingly connected to one calibrated unit 103. That is, each of the logic conversion circuits is configured to receive the first calibration code ZQPU<5:0> and the second calibration code ZQPU_CM<3:0>, and perform calculation on the received first calibration code ZQPU<5:0> and the received second calibration code ZQPU_CM<3:0>, to obtain a third calibration code ZQPU_loc_dqm_<5:0>The multiple calibrated units 103 are configured to receive the third calibration code ZQPU_loc_dqm_<5:0>until adjusted and calibrated resistance values of the calibrated units 103 are adjusted to the target resistance value. Referring to FIG. 1 and FIG. 2, in the process of calibrating the calibrated units 103, in a case that the initial reference voltage Vref_ZQPU is determined, the first calibration code ZQPU<5:0> is a fixed value. Each of the logic conversion circuits 102 may be a full adder. Calculation is performed on the first calibration code ZQPU<5:0> and the second calibration code ZQPU_CM<3:0> by the full adder to obtain the third calibration code ZQPU_loc_dqm_<5:0>. For example, when the first calibration code ZQPU<5:0> is “000000” and the second calibration code ZQPU_CM<3:0> is “0001”, the third calibration code ZQPU_loc_dqm_<5:0>calculated by the full adder is “000001”. When the third calibration code ZQPU_loc_dqm_<5:0>calculated and outputted by one of the logic conversion circuits 102 calibrates a corresponding connected calibrated unit 103 to reach the required target resistance value, after the calibrated unit 103 (DQ₀ Local Block) traverses ZQPU_CM<3:0>, it is confirmed that a level of a corresponding logic conversion circuit 102 is “1”. In this case, the logic conversion circuit 102 burns a bias level corresponding to ZQPU_CM<3:0> into a redundant circuit corresponding to the logic conversion circuit102 (DQ₀ Adder), and then the first calibration code ZQPU<5:0> is fixedly subjected to a logical operation, in the logic conversion circuit 102, with a fixed calibration code Fuse_dq0<3:0> of the redundant circuit to obtain a third calibration code ZQPU_loc_dq0_<5:0>, namely, a third calibration code ZQPU_loc_dq0_<5:0>obtained after the logical operation of the second calibration code ZQPU_CM<3:0>corresponding to the level “1”. After the resistance value of one of the calibrated units 103 is adjusted, the remaining logic conversion circuits 102 continue to receive the first calibration code ZQPU<5:0> and the second calibration code ZQPU_CM<3:0>. When the calibrated unit 103 (DQ1 Local Block) reaches the target resistance value, and the level of the corresponding logic conversion circuit 102 is “2”, the logic conversion circuit 102 burns a bias level corresponding to the second calibration code ZQPU_CM<3:0>corresponding to the level “2” into a redundant circuit corresponding to the logic conversion circuit 102 (DQ1 Adder), and then the first calibration code ZQPU<5:0> is fixedly subjected to a logical operation, in the logic conversion circuit 102, with a fixed calibration code Fuse_dq1<3:0> of the redundant circuit to obtain a third calibration code ZQPU_loc_dq0_<5:0>, namely, a third calibration code ZQPU_loc_dq1_<5:0>obtained after the logical operation of the second calibration code ZQPU_CM<3:0>corresponding to the level “2”, and so on, until resistance value adjustment of all the calibrated units 103 is completed. That is, the adjustment of all the calibrated units 103 is ended when the calibrated resistance values of all the calibrated units 103 reach the target resistance value. The bias level may be understood as a value of the corresponding fixed calibration code Fuse_dq1<3:0>after the second calibration code ZQPU_CM<3:0> is burned into the redundant circuit when the calibrated unit 103 reaches the target resistance value. That is, the value of the second calibration code ZQPU_CM<3:0> and the value of the burned fixed calibration code Fuse_dq1<3:0> are the same. The fixed calibration code Fuse_dqm<3:0> of the redundant circuit may be any one of Fuse_dq1<3:0> to Fuse_dqn+1<3:0>.

Multiple logic conversion circuits 102 are correspondingly connected to the calibrated units 103, and the calibrated resistance value of each of the calibrated units 103 is accurately adjusted according to a difference between the calibrated resistance value of each of the calibrated units and the target resistance value, so that the calibrated resistance value of each of the calibrated units 103 can be finely adjusted, and therefore the calibrated resistance value of each of the calibrated units 103 can reach the target resistance value. The target resistance value is a resistance value required for the calibrated units to calibrate interface impedance of the memory. That is, the target resistance value is set according to impedance calibration requirements of a data input/output signal DQ of the memory. For example, the target resistance value may be a calibrated resistance value specified in a design specification (SPEC: Standard Performance Evaluation Corporation).

In some embodiments, the target resistance values of the calibrated units 103 may be the same. That is, the multiple calibrated units 103 may be adjusted to reach the same target resistance value. For example, the target resistance values may all be 40Ω. In another embodiment, the target resistance values of the calibrated units 103 may alternatively be different, which is not limited herein.

In some embodiments, after the calibration control circuit 101 receives an exit calibration command Exit_Cal to end calibration, the multiple calibrated units 103 may have multiple different resistance values. For example, the resistance value of the reference resistor RZQ is 240Ω; and after calibration, resistance values that can be obtained by the calibrated units 103 include: 240 Ω, 120 Ω, 80Ω, and 40Ω. During ODT circuit adjustment, the ODT resistance value may be adjusted to different resistance values such as 240 Ω, 120 Ω, 80 Ω, 60 Ω, 48 Ω, 40Ω, and 34Ω by selecting an appropriate calibrated unit 103, namely by changing the number of transistors in a calibrated unit 103 or the number of calibrated units 103 connected in parallel. It may be understood that the number of transistors included in each of the calibrated units 103 may be the same or different.

In some embodiments, referring to FIG. 4 and FIG. 5, the memory 10 may be any one of various memory devices supporting high-speed operation. For example, the memory may include, but is not limited to, a DDR4 memory, a DDR5 memory, a DDR6 memory, an LPDDR4 memory, an LPDDR5 memory, or an LPDDR6 memory. For example, an impedance calibration circuit 100 is arranged in the memory 10, and in the memory 10, a calibration operation may be performed on impedance of a DQ pin of the memory 10 in response to an impedance calibration command transmitted by a memory controller 20 and based on multiple calibrated units 103 that have been calibrated. For example, the memory 10 responds to the impedance calibration command transmitted by the memory controller 20, that is, the calibration control circuit 101 in the impedance calibration circuit 100 starts to calibrate impedance of multiple calibrated units 103 after receiving the data calibration command Enter_Cal. In addition, the memory controller 20 may further transmit a stop calibration command to the memory 10. That is, when receiving the exit calibration command Exit_Cal, the calibration control circuit stops calibrating the impedance of the multiple calibrated units 103.

Before the memory 10 transmits and/or receives data, the impedance calibration circuit 100 performs an impedance calibration operation, and after the calibration is completed, input/output impedance of the memory 10 is adjusted to reduce or eliminate impedance mismatch between the memory 10 and the memory controller 20, thereby facilitating high-speed data transmission.

Another embodiment of the present disclosure further provides a storage system. Referring to FIG. 5, a storage system 30 includes at least one memory 10 and a memory controller 20 coupled to the at least one memory. The storage system 30 may be implemented in a module structure, e.g., a dual-in-line memory module (DIMM, Dual-Inline-Memory-Module or a high bandwidth memory (HBM, High Bandwidth Memory) device. In the module structure, the memory 10 and the memory controller 20 are integrated into one substrate. The memory controller 20 may transmit a write command, a read command, and an impedance calibration command to the memory 10 under the control of a host or a test bench. The memory 10 may perform a write operation in response to the write command, perform a read operation in response to the read command, and perform an impedance calibration operation in response to the impedance calibration command.

A person of ordinary skill in the art may understand that the foregoing implementations are specific embodiments for implementing the present disclosure. In an actual application, various modifications may be made to the forms and details of the implementations without departing from the spirit and scope of the embodiments of the present disclosure. Any person skilled in the art may make changes and modifications without departing from the spirit and scope of the embodiments of the present disclosure. Therefore, the protection scope of the embodiments of the present disclosure shall be subject to the scope defined by the claims.

What is claimed is:

1. An impedance calibration circuit, comprising:
a calibration control circuit, configured to output a first calibration code;
logic conversion circuits, configured to receive the first calibration code and a second calibration code, perform calculation on the first calibration code and the second calibration code, and then output a third calibration code; and
a plurality of calibrated units, configured to receive the third calibration code and adjust impedance based on the third calibration code.

2. The impedance calibration circuit according to claim 1, wherein when calibrated resistance values of the calibrated units are adjusted to a target resistance value, the logic conversion circuits are further configured to perform bias latching on the second calibration code corresponding to the third calibration code.

3. The impedance calibration circuit according to claim 1, wherein a plurality of logic conversion circuits are correspondingly connected to the calibrated units.

4. The impedance calibration circuit according to claim 1, wherein the calibrated units are pull-up calibrated units, and the plurality of pull-up calibrated units are connected in parallel.

5. The impedance calibration circuit according to claim 4, wherein each of the pull-up calibrated units comprises a plurality of PMOS transistors connected in parallel.

6. The impedance calibration circuit according to claim 5, wherein each of the logic conversion circuits comprises a full adder.

7. An impedance calibration method, comprising:
determining an initial reference voltage of an impedance calibration circuit, and latching the initial reference voltage; and
traversing a plurality of calibrated units of the impedance calibration circuit under the initial reference voltage until a calibrated resistance value of each of the calibrated units is adjusted to a target resistance value.

8. The impedance calibration method according to claim 7, wherein the determining an initial reference voltage of an impedance calibration circuit, and latching the initial reference voltage comprises:
selecting one of the calibrated units as an initial calibrated unit; and
adjusting a calibrated resistance value of the initial calibrated unit under different reference voltages, and determining and latching the initial reference voltage corresponding to the target resistance value when the calibrated resistance value of the initial calibrated unit is the target resistance value.

9. The impedance calibration method according to claim 8, wherein the traversing a plurality of calibrated units of the impedance calibration circuit under the initial reference voltage until a calibrated resistance value of each of the calibrated units is adjusted to a target resistance value further comprises latching a bias level corresponding to the target resistance value of each of the calibrated units.

10. The impedance calibration method according to claim 8, wherein the target resistance values of the calibrated units are the same.
